(19) United States
(12) Patent Application Publication
(10) Pub. No.: US 2024/0324292 A1
(43) Pub. Date: Sep. 26, 2024

(54) DISPLAY DEVICE

(71) Applicant: Samsung Display Co., Ltd., Yongin-si (KR)

(72) Inventors: TAEHYOUNG NO, Yongin-si (KR); YOUNG-SOO YOON, Yongin-si (KR); BONGWON LEE, Yongin-si (KR)

(21) Appl. No.: 18/387,201

(22) Filed: Nov. 6, 2023

(30) Foreign Application Priority Data
Mar. 24, 2023 (KR) 10-2023-0038934

(51) Int. Cl. H10K 59/121; G09G 3/20; H10K 59/131

(52) U.S. Cl. CPC H10K 59/1216; G09G 3/20; H10K 59/131; G09G 2300/0852; H10K 59/1213

(57) ABSTRACT

A display device includes a substrate having a non-rectangular display area, a plurality of pixels disposed in the display area on the substrate and disposed in a plurality of pixel columns extending along a first direction and a plurality of pixel rows extending along a second direction crossing the first direction, and a compensation pattern disposed adjacent to a pixel disposed in an uppermost pixel row among the plurality of pixels in the first direction.

This application claims priority to Korean Patent Application No. 10-2023-0038934, filed on Mar. 24, 2023, and all the benefits accruing therefrom under 35 U.S.C. § 119, the content of which in its entirety is herein incorporated by reference.

### BACKGROUND

### 1. Field

The disclosure relates to a display device, and more particularly to an atypical display device.

### 2. Description of the Related Art

As information technology develops, the importance of a display device as a connection medium between a user and information is being highlighted. For example, the use of display devices such as a liquid crystal display device (LCD), an organic light emitting display device (OLED), a plasma display device (PDP), a quantum dot display device or the like is increasing.

Such a display device includes a plurality of pixels. Each of the plurality of pixels includes at least a transistor and a driving element. The driving element includes various metals. A capacitor is formed by stacking various metals with an insulating layer interposed therebetween.

### SUMMARY

The present disclosure relates to a display device with an improved display quality.

Embodiments of a display device include a substrate, a plurality of pixels, and a compensation pattern. The substrate may have a non-rectangular display area. The plurality of pixels may be disposed in the display area on the substrate and may be disposed in a plurality of pixel columns extending along a first direction and a plurality of pixel rows extending along a second direction crossing the first direction. The compensation pattern may be disposed adjacent to a pixel disposed in an uppermost pixel row among the plurality of pixels in the first direction.

In an embodiment, the compensation pattern may include a first metal pattern disposed on the substrate and a second metal pattern disposed on the first metal pattern. A first compensation capacitor may be formed in an area where the first metal pattern and the second metal pattern overlap each other.

In an embodiment, the plurality of pixels may include a first transistor and a second transistor. The first transistor may include a first active pattern, a first gate pattern, a first source electrode, and a first drain electrode. The first metal pattern may include a same material as the first gate pattern.

In an embodiment, the display device may further include a capacitor electrode pattern overlapping the first gate pattern. A storage capacitor may be formed in an area where the capacitor electrode pattern and the first gate pattern overlap each other. The second metal pattern may include a same material as the capacitor electrode pattern.

In an embodiment, the compensation pattern may further include a third metal pattern disposed on the second metal pattern. A second compensation capacitor may be formed in an area where the second metal pattern and the third metal pattern overlap each other.

In an embodiment, the second transistor may include a second active pattern, a second gate pattern, a second source electrode, and a second drain electrode. The third metal pattern may include a same material as the second gate pattern.

In an embodiment, the compensation pattern may further include a fourth metal pattern disposed on the second metal pattern. A third compensation capacitor may be formed in an area where the third metal pattern and the fourth metal pattern overlap each other.

In an embodiment, the fourth metal pattern may include a same material as the first source electrode and the first drain electrode.

In an embodiment, the compensation pattern may be disposed to correspond to each pixel column.

In an embodiment, the display device may further include a plurality of data lines connected to the plurality of pixels located in a corresponding pixel column among the plurality of pixel columns, extending in the first direction, and spaced apart from each other in the second direction. Each of the plurality of data lines may have a different internal capacitance. The compensation pattern may provide a compensation capacitance for compensating a deviation of the internal capacitance between the plurality of data lines.

In an embodiment, the compensation capacitance may increase as a distance from a virtual line passing through a center of the display area and extending in the first direction increases.

Another embodiment of a display device includes a substrate, a plurality of pixels, and a compensation pattern. The substrate may have a non-rectangular display area. The plurality of pixels may be disposed in the display area on the substrate and disposed in a plurality of pixel columns extending along a first direction. The compensation pattern may include a first sub compensation pattern disposed adjacent to a first sub pixel included in a pixel disposed in an uppermost pixel row among the plurality of pixels in the first direction and a second sub compensation pattern disposed adjacent to a second sub pixel included in the pixel and having an internal capacitance different from an internal capacitance of the first sub pixel in the first direction.

In an embodiment, each of the first sub compensation pattern and the second sub compensation pattern may provide a different compensation capacitance.

In an embodiment, the plurality of pixels may include a first transistor and a second transistor. The first transistor may include a first active pattern, a first gate pattern, a first source electrode, and a first drain electrode. The compensation pattern may include a first metal pattern disposed on the substrate and a second metal pattern disposed on the first metal pattern. A first compensation capacitor may be formed in an area where the first metal pattern and the second metal pattern overlap each other. The first metal pattern may include a same material as the first gate pattern.

In an embodiment, the display device may further include a capacitor electrode pattern overlapping the first gate pattern. A storage capacitor may be formed in an area where the capacitor electrode pattern and the first gate pattern overlap each other. The second metal pattern may include a same material as the capacitor electrode pattern.

In an embodiment, the second transistor may include a second active pattern, a second gate pattern, a second source electrode, and a second drain electrode. The compensation pattern may further include a third metal pattern disposed on the second metal pattern. A second compensation capacitor may be formed in an area where the second metal pattern and the third metal pattern overlap each other. The third metal pattern may include a same material as the second gate pattern.

In an embodiment, the compensation pattern may further include a fourth metal pattern disposed on the second metal pattern. A third compensation capacitor may be formed in an area where the third metal pattern and the fourth metal pattern overlap each other. The fourth metal pattern may include a same material as the first source electrode and the first drain electrode.

In an embodiment, the compensation pattern may be disposed to correspond to each pixel column.

In an embodiment, the display device may further include a plurality of data lines connected to the plurality of pixels located in a corresponding pixel column among the plurality of pixel columns, extending in the first direction, and spaced apart from each other in the second direction. Each of the plurality of data lines may have a different internal capacitance. The compensation pattern may provide a compensation capacitance for compensating a deviation of the internal capacitance between the plurality of data lines.

In an embodiment, the compensation capacitance may increase as a distance from a virtual line passing through a center of the display area and extending in the first direction increases.

As described above, according to embodiments, a display device may include a display device include a substrate, a plurality of pixels, and a compensation pattern. The substrate may have a non-rectangular display area. The plurality of pixels may be disposed in the display area on the substrate and may be disposed in a plurality of pixel columns extending along a first direction and a plurality of pixel rows extending along a second direction crossing the first direction. The compensation pattern may be disposed adjacent to a pixel disposed in an uppermost pixel row among the plurality of pixels in the first direction. In such embodiments, since the display device includes the compensation pattern, occurrence of a horizontal line in the display device may be prevented or reduced.

### BRIEF DESCRIPTION OF THE DRAWINGS

Illustrative, non-limiting embodiments will be more clearly understood from the following detailed description in conjunction with the accompanying drawings.

FIG. 1 is a plan view of a display device according to an embodiment.

FIG. 2 is a plan view illustrating a plurality of pixels included in the display device of FIG. 1, according to an embodiment.

FIG. 3 is a plan view illustrating a compensation pattern included in the display device of FIG. 1, according to an embodiment.

FIG. 4 is an enlarged plan view of area A of FIG. 3, according to an embodiment.

FIG. 5 is a cross-sectional view taken along line I-I′ of FIG. 4, according to an embodiment.

FIG. 6 is a plan view of the display device of FIG. 1, illustrating the sub compensation patterns included in the compensation pattern of FIG. 4, according to an embodiment.

FIG. 7 is a cross-sectional view of the display device of FIG. 1, taken along line II-II′ of FIG. 6, according to an embodiment.

FIG. 8 is a cross sectional view of a compensation pattern of the display device of FIG. 1, according to a first embodiment.

FIG. 9 is a cross-sectional view of a compensation pattern of the display device of FIG. 1, according to a second embodiment.

FIG. 10 is a cross-sectional view of a compensation pattern of the display device of FIG. 1, according to a third embodiment.

FIG. 11 is a graph illustrating an effect of display devices, according to an embodiment.

FIG. 12 is a graph illustrating an effect of display devices, according to an embodiment.

FIG. 13 is a graph illustrating an effect of display devices, according to an embodiment.

FIG. 14 is a plan view illustrating a display device, according to another embodiment.

FIG. 15 is a cross-sectional view taken along line IV-IV′ of FIG. 14, according to an embodiment.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element (or a region, a layer, a portion, or the like) is referred to as being related to another element such as being “on”, “connected to” or “coupled to” another element, it can be directly disposed on, connected or coupled to the other element, or intervening elements may be disposed therebetween.

Like reference numerals refer to like elements. In addition, in the drawings, the thickness, the ratio, and the dimensions of elements are exaggerated for an effective description of technical contents.

The term “and/or,” includes all combinations of one or more of which associated configurations may define.

It will be understood that, although the terms first, second, etc. may be used herein to describe various elements, these elements should not be limited by these terms. These terms are only used to distinguish one element from another element. For example, a first element may be referred to as a second element, and similarly, a second element may be referred to as a first element without departing from the teachings of the present disclosure.

The terminology used herein is for the purpose of describing particular embodiments only and is not intended to be limiting. As used herein, “a”, “an,” “the,” and “at least one” do not denote a limitation of quantity, and are intended to include the plural forms as well, unless the context clearly indicates otherwise. Within the Figures and the text of the disclosure, a reference number indicating a singular form of an element may also be used to reference a plurality of the singular element.

Also, terms of “below”, “on lower side”, “above”, “on upper side”, or the like may be used to describe the relationships of the components shown in the drawings. The terms are used as a relative concept and are described with reference to the direction indicated in the drawings.

It should be understood that the terms “comprise”, or “have” are intended to specify the presence of stated features, integers, steps, operations, elements, components, or combinations thereof in the disclosure, but do not preclude the presence or addition of one or more other features, integers, steps, operations, elements, components, or combinations thereof.

As used herein, being “disposed directly on” may mean that there is no additional layer, film, region, plate, or the like between a part and another part such as a layer, a film, a region, a plate, or the like. For example, being “disposed directly on” may mean that two layers or two members are disposed without using an additional member such as an adhesive member, therebetween.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within +30%, 20%, 10% or 5% of the stated value.

Unless otherwise defined, all terms (including technical and scientific terms) used herein have the same meaning as commonly understood by one of ordinary skill in the art to which the present disclosure belongs. In addition, terms, such as those defined in commonly used dictionaries, should be interpreted as having a meaning that is consistent with their meaning in the context of the relevant art and should not be interpreted in an idealized or overly formal sense unless expressly so defined herein.

Hereinafter, embodiments of the invention will be described with reference to the accompanying drawings.

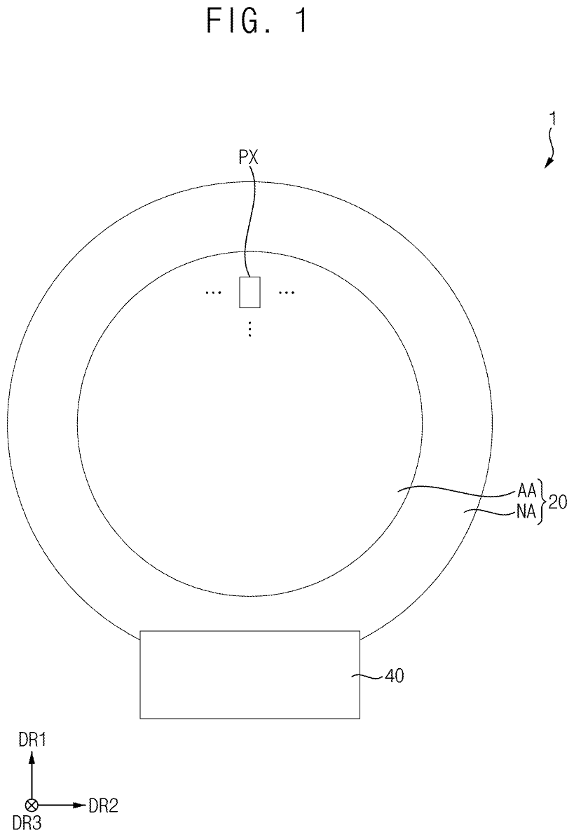

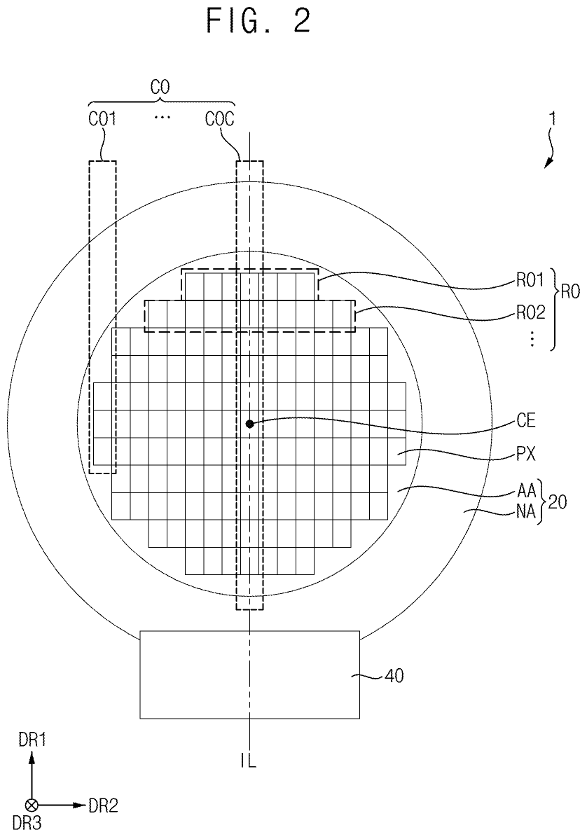

FIG. 1 is a plan view of a display device, according to an embodiment, and FIG. 2 is a plan view illustrating a plurality of pixels included in the display device of FIG. 1, according to an embodiment.

In an embodiment, FIG. 1 is a plan view illustrating a display panel 20 and a signal input part 40 of a display device 1, and FIG. 2 is a plan view illustrating an arrangement of a plurality of pixels PX in the display device 1.

In an embodiment, the display device 1 may include the display panels 20 having various planar shapes. For example, the display device 1 may have various planar shapes such as a circular shape, an elliptical shape, a polygonal shape, or the like. However, the disclosure is not limited thereto.

In an embodiment, a plane may be defined by a first direction DR1 and a second direction DR2. The second direction DR2 may cross the first direction DR1. For example, the first direction DR1 and the second direction DR2 may be perpendicular to each other.

In an embodiment, the display panel 20 may have a flexible characteristic. For example, the display panel 20 may be a curved display panel having a partially curved shape.

In an embodiment, the display panel 20 may include a display area AA and a non-display area NA. For example, the display area AA may be defined as an area where an image is displayed, and the non-display area NA may be defined as an area where the image is not displayed.

In an embodiment, the display area AA may have a non-rectangular planar shape. For example, the display area AA may have various planar shapes such as a circular shape, an elliptical shape, a polygonal shape (except for a rectangular shape), or the like. However, the invention is not limited thereto. For example, the display area AA may have various planar shapes including curved lines.

In an embodiment, the plurality of pixels PX may be disposed in the display area AA. Each of the plurality of pixels PX may be disposed at a position where a plurality of pixel rows RO and a plurality of pixel columns CO intersect. The plurality of pixel columns CO may extend along the first direction DR1. The plurality of pixel rows RO may extend along the second direction DR2. That is, the plurality of pixel columns CO and the plurality of pixel rows RO may cross each other.

In an embodiment, first to m-th pixels may be disposed in each of the plurality of pixel rows RO. The m may be a natural number greater than 1 (one). For example, the plurality of pixel rows RO may include a first row RO1 and a second row RO2. The second row RO2 may mean a pixel row positioned second from the first row RO1 in a direction opposite to the first direction DR1. Hereinafter, the first row RO1 may refer to an uppermost pixel row RO1.

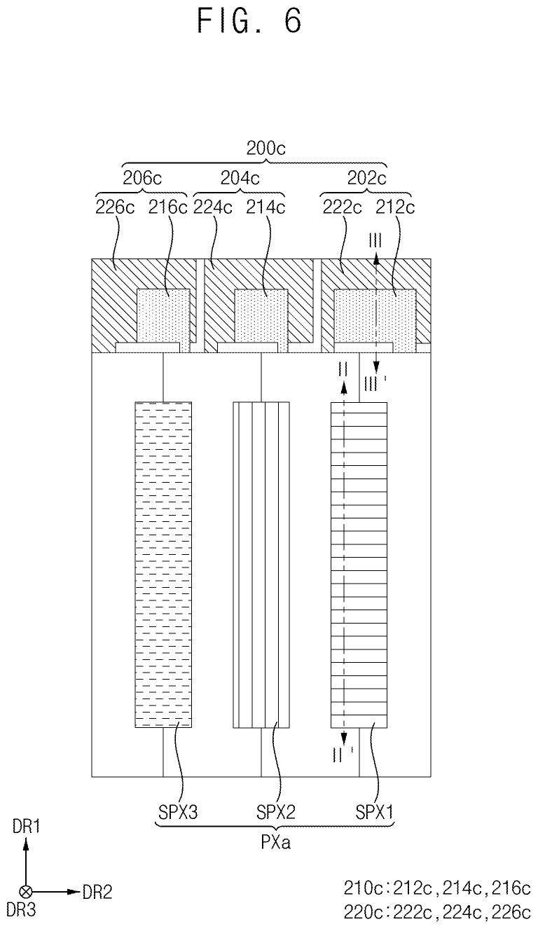

In an embodiment, a pixel disposed in the uppermost pixel row RO1 may include a plurality of sub pixels (e.g., a first sub pixel SPX1, a second sub pixel SPX2, and a third sub pixel SPX3 of FIG. 6). In FIG. 2, it is shown that the number of pixels disposed in the uppermost pixel row RO1 is 7, however, the disclosure is not limited thereto. For example, one or two or more pixels may be disposed in the uppermost pixel row RO1.

In an embodiment, first to n-th pixels may be disposed in each of the plurality of pixel columns CO. The n may be a natural number greater than 1 (one). For example, the plurality of pixel columns CO may include a first column CO1, a c-th column, and a central column COC. Similar to the foregoing, the c-th column may refer to a pixel column located c-th from the first column CO1 in the second direction DR2.

In an embodiment, in a plan view, the plurality of pixels PX located in the central column COC pass through a center CE of the display area AA and overlap a virtual line IL extending in the first direction DR1. For example, based on the virtual line IL, the plurality of pixels PX may be disposed symmetrically left and right.

In an embodiment, each of the plurality of pixels PX may emit light. The light emitted from each of the plurality of pixels PX may be combined and displayed as the image.

In an embodiment, the image may be displayed in a direction opposite to a third direction DR3. The third direction DR3 may cross each of the first and second directions DR1 and DR2, respectively. For example, the first direction DR1, the second direction DR2, and the third direction DR3 may be perpendicular to each other.

In an embodiment, the non-display area NA may surround the display area AA. The plurality of pixels PX may not be disposed in the non-display area NA. In other words, the image may not be displayed in the non-display area NA. However, the disclosure is not limited thereto. For example, the non-display area NA may surround only a portion of the display area AA.

In an embodiment, the signal input part 40 may include a data driver for supplying a data signal.

In an embodiment, the signal input part 40 may be disposed on one side of the display panel 20. For example, the signal input part 40 may be disposed in the non-display area NA.

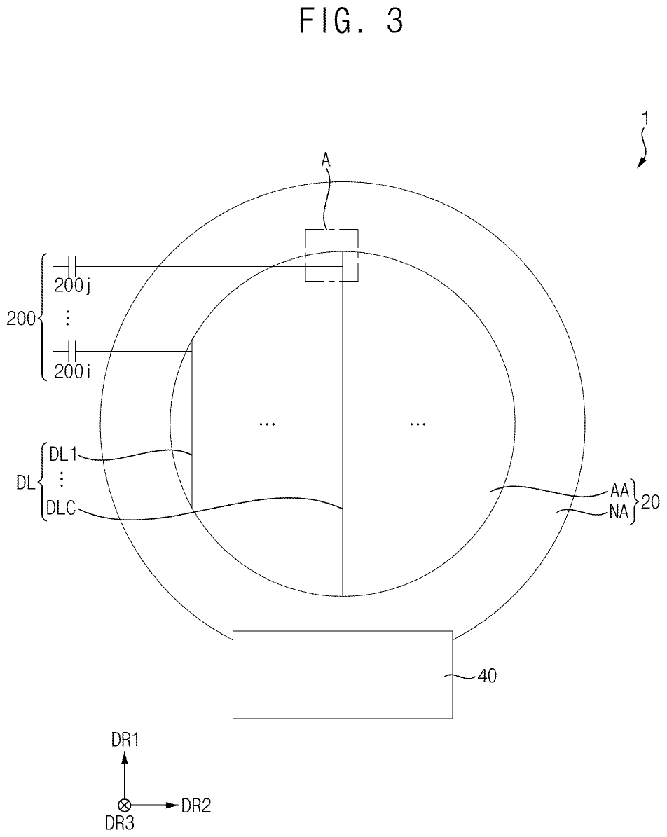

In an embodiment, the signal input part 40 may generate signals corresponding to a plurality of data lines (e.g., a plurality of data lines DL of FIG. 3) and a plurality of scan lines disposed on the display panel 20.

In an embodiment, the plurality of scan lines may cross the plurality of data lines. For example, the plurality of scan lines may be spaced apart from each other in the first direction DR1 and may extend in the second direction DR2. The plurality of data lines may be spaced apart from each other in the second direction DR2 and may extend from each other in the first direction DR1. A detailed description of the plurality of data lines DL will be described later with reference to FIG. 3.

For example, in an embodiment, the signal input part 40 may generate driving signals, wherein the driving signals include signals corresponding to the plurality of data lines, and signals corresponding to the plurality of scan lines. The driving signal may drive a driving circuit of the display panel 20. The signals corresponding to the plurality of data lines may be provided to the plurality of data lines and the signals corresponding to the plurality of scan lines may be provided to the plurality of scan lines.

In an embodiment and referring to FIGS. 1 and 2, the signal input part 40 may be spaced farthest from a bottom row of the plurality of pixels PX (e.g., a top pixel row R01 in the opposite direction to the first direction DR1), however, the invention is not limited thereto. The signal input part 40 may be disposed at various locations in the display device 1.

For example, the display device 1 may be a smart watch. In this case, the display area AA of the display panel 20 may have a circular planar shape. However, the invention is not limited thereto. Alternatively, the display device 1 may be a variety of electronic devices including the display panel 20 in which the display area AA having a non-rectangular flat shape is defined.

FIG. 3 is a plan view illustrating a compensation pattern included in the display device of FIG. 1, according to an embodiment.

In an embodiment and referring to FIGS. 2 and 3, the display device 1 may include the plurality of data lines DL and a plurality of compensation patterns 200.

In an embodiment, the plurality of data lines DL and the plurality of pixels PX may be disposed in the display area AA.

In an embodiment, each of the plurality of data lines DL may extend in the first direction DR1. Each of the plurality of data lines DL may be spaced apart from each other along the second direction DR2. Each of the plurality of data lines DL may be connected to the signal input part 40.

In an embodiment and referring to FIG. 2, for convenience of explanation, a connection relationship between the plurality of data lines DL and the signal input part 40 is omitted and illustrated. The plurality of data lines DL and the signal input part 40 may be connected in various ways. For example, the plurality of data lines DL and the signal input part 40 may be connected in the first direction DR1. As another example, a structure connected at an angle to the first direction DR1 may be included between the plurality of data lines DL and the signal input part 40.

In an embodiment, the plurality of data lines DL may include a first data line DL1 and a c-th data line DLC. For example, the c-th data line DLC may be positioned at a c-th position away from the first data line DL1 in the second direction DR2. The c may be a natural number greater than 1 (one).

In an embodiment and referring to FIG. 2, only the plurality of data lines DL located on a left side of the plane defined by the first and second directions DR1 and DR2 are shown. For example, the c-th data line DLC may be a data line located in a central column among the plurality of data lines DL. For example, when the display device 1 includes 380 data lines DL, the c-th data line DLC may be a data line located at 190-th position away from the first data line DL1 in the second direction DR2.

In an embodiment, the plurality of data lines DL may be connected to the plurality of pixels PX located in the corresponding pixel column among the plurality of pixel columns CO. For example, the first data line DL1 may be connected to the plurality of pixels PX positioned in the first column CO1.

In an embodiment, each of the plurality of data lines DL may have a different internal capacitance. For example, the internal capacitance of the c-th data line DLC may be greater than the internal capacitance of the first data line DL1.

In an embodiment, the display device 1 may include the plurality of compensation patterns 200 for compensating a deviation of the internal capacitance between the plurality of data lines DL.

In an embodiment, the plurality of compensation patterns 200 may include a j-th compensation pattern 200j and an i-th compensation pattern 200i. For example, the j-th compensation pattern 200j may be disposed at a position overlapping the virtual line IL in the plan view. In other words, the j-th compensation pattern 200j may be a compensation pattern located in the central column COC among the plurality of compensation patterns 200. The i-th compensation pattern 200i may be a compensation pattern located farthest from the c-th compensation pattern 200c among the plurality of compensation patterns 200 in a direction opposite to the second direction DR2. For example, the i may be a natural number greater than or equal to 1, and the j may be a natural number greater than the i.

In an embodiment, in order to compensate for the deviation of the internal capacitance between the plurality of data lines DL, each of the plurality of compensation patterns 200 may provide a different compensation capacitance. For example, the compensation capacitance provided by each of the plurality of compensation patterns 200 may increase as a distance from the virtual line IL increases. For example, the compensation capacitance of the j-th compensation pattern 200j may be greater than the compensation capacitance of the i-th compensation pattern 200i.

Accordingly, in an embodiment, a sum of the internal capacitance of the data line connected to the i-th pixel column among the plurality of data lines DL and the compensation capacitance of the compensation pattern disposed to correspond to the i-th pixel column (i.e., a total cap) may be constant.

In an embodiment, the compensation capacitance may be determined based on a maximum value of the internal capacitance. For example, the maximum value of the internal capacitance may be about equal to the internal capacitance of the c-th data line DLC connected to the central column COC. In other words, the total cap may be determined based on the internal capacitance of the c-th data line DLC connected to the central column COC.

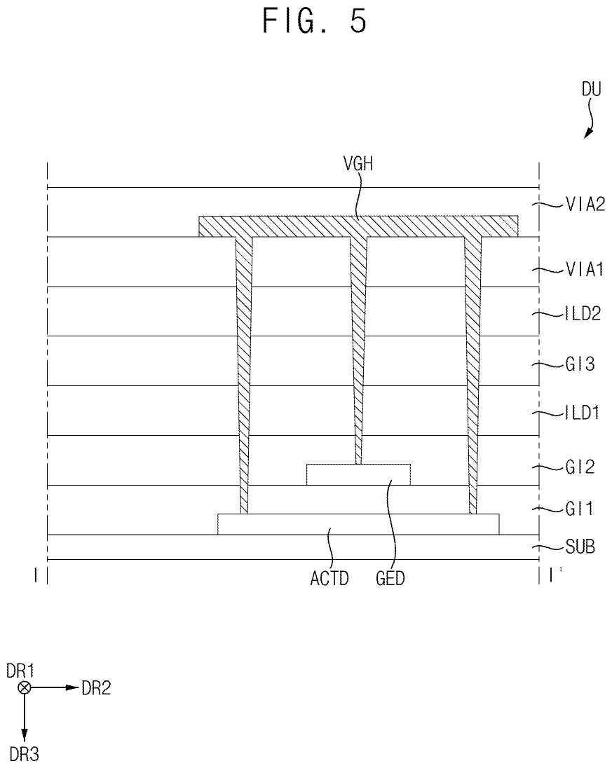

A detailed description of an arrangement and structure of the plurality of compensation patterns 200 will be described later with reference to FIGS. 5, 6, 7, 8, 9, and 10, according to an embodiment.

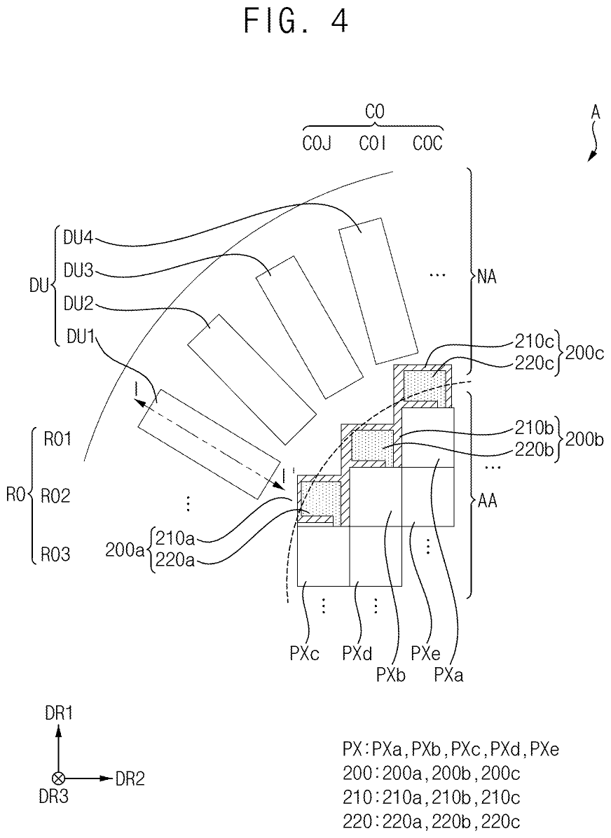

FIG. 4 is an enlarged view of area A of FIG. 3, according to an embodiment.

In an embodiment and referring to FIGS. 3 and 4, the display device 1 may include a plurality of dummy driving units DU.

In an embodiment, a plurality of pixels PX may be disposed in the display area AA. For example, the plurality of pixels PX may include a first pixel PXa, a second pixel PXb, a third pixel PXc, a fourth pixel PXd, and a fifth pixel PXe.

As described above, in an embodiment, the plurality of pixels PX may be disposed in the plurality of pixel columns CO. For example, the first pixel PXa and the fifth pixel PXe may be disposed in the central column COC. The second pixel PXb and the fourth pixel PXd may be disposed in an i-th column COI adjacent to the central column COC in the direction opposite to the second direction DR2. The third pixel PXc may be disposed in a j-th column COJ adjacent to the i-th column COI in the direction opposite to the second direction DR2. The j may be a natural number greater than or equal to 1, and the i may be a natural number greater than j.

In an embodiment, the plurality of pixels PX may be disposed in the plurality of pixel rows RO. For example, the first pixel PXa may be disposed in the uppermost pixel row RO1. The second pixel PXb and the fifth pixel PXe may be disposed in the second row RO2 adjacent to the uppermost pixel row. The third pixel PXc and the fourth pixel PXd may be disposed in a third row RO3 adjacent to the second row RO2.

In an embodiment, the plurality of compensation patterns 200 may be disposed to correspond to each of the plurality of pixel columns CO. For example, a first compensation pattern 200a may be disposed in the j-th column COJ. A second compensation pattern 200b may be disposed in the i-th column COI. A third compensation pattern 200c may be disposed in the central column COC. More specifically, the first compensation pattern 200a may be disposed adjacent to the third pixel PXc. The second compensation pattern 200b may be disposed adjacent to the second pixel PXb. The third compensation pattern 200c may be disposed adjacent to the first pixel PXa.

In an embodiment, the plurality of compensation patterns 200 disposed adjacent to the pixel disposed in the uppermost pixel row RO1 among the plurality of pixels PX may include a plurality of sub compensation patterns (e.g., a first sub compensation pattern 202c, a second sub compensation pattern 204c, and a third sub compensation pattern 206c of FIG. 6). A detailed description of the plurality of sub compensation patterns will be described later with reference to FIG. 6.

In an embodiment, the plurality of compensation patterns 200 may include a first metal pattern 210 and a second metal pattern 220. The second metal pattern 220 may be disposed on the first metal pattern 210. For example, the first metal pattern 210 may include a first compensation metal pattern 210a, a second compensation metal pattern 210b, and a third compensation metal pattern 210c. The second metal pattern 220 may include a fourth compensation metal pattern 220a, a fifth compensation metal pattern 220b, and a sixth compensation metal pattern 220c.

In an embodiment, for example, the first compensation pattern 200a may include the first compensation metal pattern 210a and the fourth compensation metal pattern 220a. The fourth compensation metal pattern 220a may be disposed on the first compensation metal pattern 210a.

In an embodiment, for example, the second compensation pattern 200b may include the second compensation metal pattern 210b and the fifth compensation metal pattern 220b. The fifth compensation metal pattern 220b may be disposed on the second compensation metal pattern 210b.

In an embodiment, for example, the third compensation pattern 200c may include the third compensation metal pattern 210c and the sixth compensation metal pattern 220c. The sixth compensation metal pattern 220c may be disposed on the third compensation metal pattern 210c.

In an embodiment, in the above, it has been described that the plurality of compensation patterns 200 include the first metal pattern 210 and the second metal pattern 220, however, the plurality of sub compensation patterns may also have substantially a same structure. For example, the plurality of sub compensation patterns may include the first metal pattern 210 and the second metal pattern 220. The second metal pattern 220 may be disposed on the first metal pattern 210.

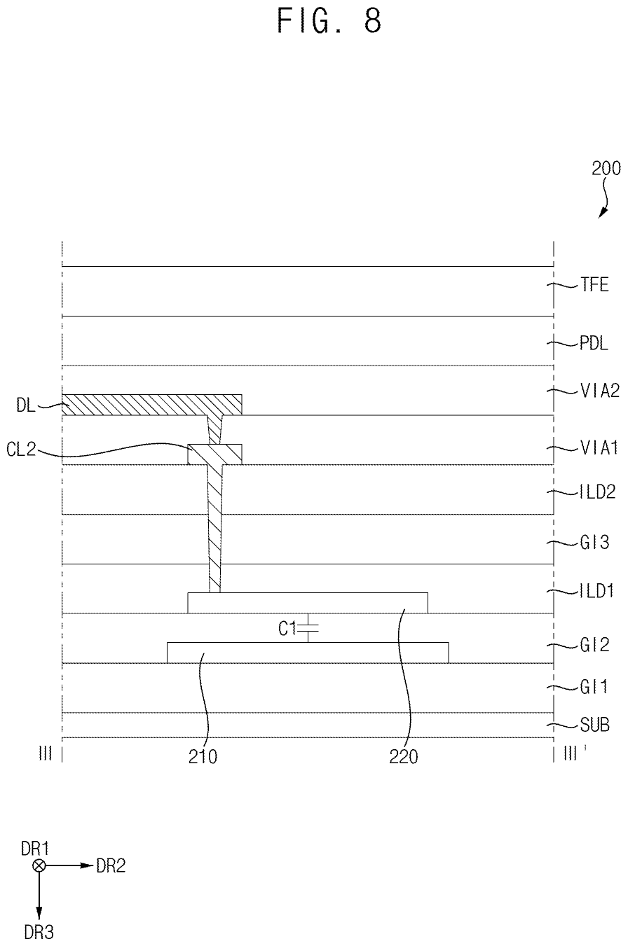

A detailed description of the first metal pattern 210 and the second metal pattern 220 will be described later with reference to FIG. 8, according to an embodiment.

In an embodiment, the plurality of dummy driving units DU may be disposed in the non-display area NA. For example, the plurality of dummy driving units DU may include a first dummy driving unit DU1, a second dummy driving unit DU2, a third dummy driving unit DU3, and a fourth dummy driving unit DU4.

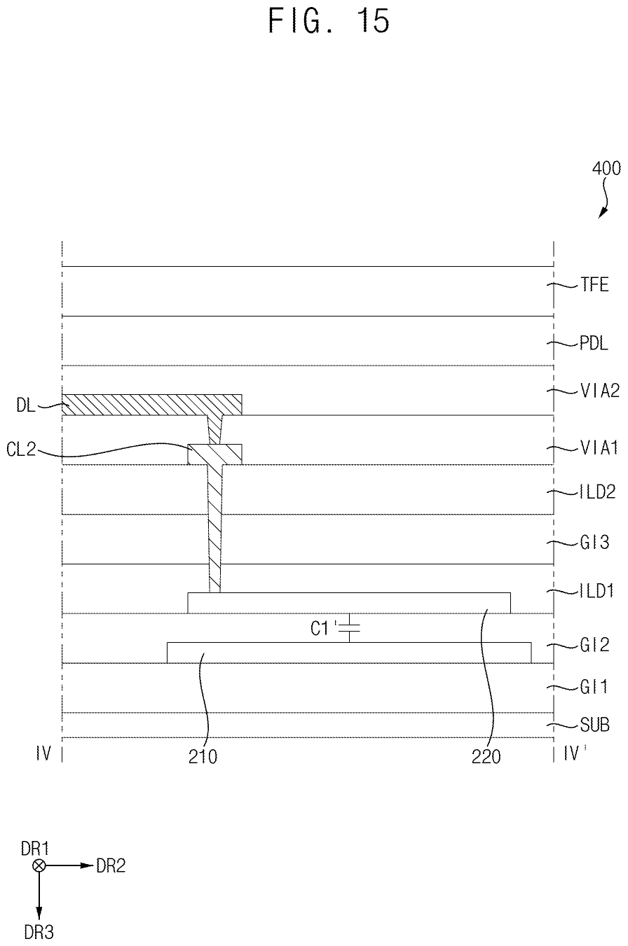

However, the invention is not limited thereto. For example, in an embodiment, in the display device 1, the plurality of dummy driving units DU may be omitted. A detailed description of a structure in which the plurality of dummy driving units DU is omitted in the display device 1 will be described later with reference to FIGS. 14 and 15, according to an embodiment.

In an embodiment, the display device 1 may be modified in various ways. For example, in FIG. 4, the plurality of pixels PX have been described as including the first pixel PXa, the second pixel PXb, the third pixel PXc, the fourth pixel PXd, and the fifth pixel PXe, however, the disclosure is not limited thereto. For example, the display device 1 may include two or more (but excluding 5) pixels PX.

In addition, in an embodiment and referring to FIG. 4, the plurality of compensation patterns 200 have been described as including the first compensation pattern 200a, the second compensation pattern 200b, and the third compensation pattern 200c, however, the invention is not limited thereto. For example, the number of the plurality of compensation patterns 200 may vary according to the number of the plurality of pixel columns CO. For example, when the display device 1 includes about 380 pixel columns, the display device 1 may include about 380 compensation patterns.

In addition, in an embodiment and referring to FIG. 4, the plurality of compensation patterns 200 have been described as including the first metal pattern 210 and the second metal pattern 220, however, the invention is not limited thereto. For example, the plurality of compensation patterns 200 may further include other metal patterns.

In addition, in an embodiment and referring to FIG. 4, the plurality of dummy driving units DU have been described as including the first dummy driving unit DU1, the second dummy driving unit DU2, the third dummy driving unit DU3, and the fourth dummy driving unit DU4 however, the disclosure is not limited thereto. For example, the display device 1 may include two, three, or five or more dummy driving units DU.

FIG. 5 is a cross-sectional view taken along line I-I′ of FIG. 4, according to an embodiment.

For example, FIG. 5 is a cross-sectional view of the plurality of dummy driving units DU, according to an embodiment.

In an embodiment and referring to FIGS. 3, 4, and 5, the display device 1 may include a substrate SUB, the plurality of dummy driving units DU, a first gate insulating layer GI1, a second gate insulating layer GI2, a first interlayer insulating layer ILD1, a third gate insulating layer GI3, a second interlayer insulating layer ILD2, a first via insulating layer VIA1, and a second via insulating layer VIA2.

In an embodiment, the substrate SUB may include an insulating material. For example, the substrate SUB may include a glass, a resin, and/or the like. These may be used alone or in combination with each other.

In addition, in an embodiment, the substrate SUB may include a flexible material. For example, the substrate SUB may include polystyrene, polyvinyl alcohol, polymethyl methacrylate, polyethersulfone, polyacrylate, polyetherimide, polyethylene naphthalate, polyethylene terephthalate, polyphenylene sulfide, polyarylate, polyimide, polycarbonate, triacetate cellulose, cellulose acetate propionate, and/or the like. These may be used alone or in combination with each other.

However, the invention is not limited thereto. In an embodiment, the substrate SUB may include various materials. For example, the substrate SUB may include a rigid material such as fiber reinforced plastic.

In an embodiment, the plurality of dummy driving units DU may be disposed on the substrate SUB in the non-display area NA. As shown in FIG. 5, the plurality of dummy driving units DU may include a dummy active pattern ACTD, a dummy gate pattern GED, and a dummy electrode pattern VGH.

In an embodiment, the dummy active pattern ACTD may be disposed on the substrate SUB. For example, the dummy active pattern ACTD may include amorphous silicon, polycrystalline silicon, single crystal silicon, low-temperature polycrystalline silicon, oxide semiconductor, or the like. These may be used alone or in combination with each other. However, the invention is not limited thereto. The dummy active pattern ACTD may include various semiconductor materials.

In an embodiment, the dummy active pattern ACTD may include a source region, a drain region, and a channel region positioned between the source region and the drain region.

In an embodiment, the first gate insulating layer GI1 may be disposed on both the substrate SUB and the dummy active pattern ACTD. For example, the first gate insulating layer GI1 may include an organic insulating material or an inorganic insulating material. Specifically, the first gate insulating layer GI1 may include silicon oxide (SiOx), silicon nitride (SiNx), silicon oxynitride (SiOxNy), benzo-cyclo-butene (BCB), an acrylic material, polyimide, or the like. These may be used alone or in combination with each other.

However, the invention is not limited thereto. The first gate insulating layer GI1 may include various insulating materials.

In an embodiment, the dummy gate pattern GED may be disposed on the first gate insulating layer GI1. For example, the dummy gate pattern GED may include metal and/or alloy. Specifically, the dummy gate pattern GED may include aluminum (Al), silver (Ag), copper (Cu), molybdenum (Mo), chromium (Cr), titanium (Ti), tantalum (Ta), and/or the like. These may be used alone or in combination with each other.

However, the invention is not limited thereto. In an embodiment, the dummy gate pattern GED may include various metal materials.

In an embodiment, the second gate insulating layer GI2 may be disposed on both the first gate insulating layer GI1 and the dummy gate pattern GED. For example, the second gate insulating layer GI2 may include an organic insulating material and/or an inorganic insulating material. Specifically, the second gate insulating layer GI2 may include silicon oxide (SiOx), silicon nitride (SiNx), silicon oxynitride (SiOxNy), benzo-cyclo-butene (BCB), an acrylic material, polyimide, and/or the like. These may be used alone or in combination with each other.

However, the invention is not limited thereto. In an embodiment, the second gate insulating layer GI2 may include various insulating materials.

In an embodiment, the first interlayer insulating layer ILD1 may be disposed on the second gate insulating layer GI2. For example, the first interlayer insulating layer ILD1 may include an insulating material. Specifically, the first interlayer insulating layer ILD1 may include an organic material. More specifically, the first interlayer insulating layer ILD1 may include polyimide, polyacryl, polysiloxane, and/or the like. These may be used alone or in combination with each other.

However, the invention is not limited thereto. In an embodiment, the first interlayer insulating layer ILD1 may include various inorganic materials.

In an embodiment, the third gate insulating layer GI3 may be disposed on the first interlayer insulating layer ILD1. For example, the third gate insulating layer GI3 may include an organic insulating material or an inorganic insulating material. Specifically, the third gate insulating layer GI3 may include silicon oxide (SiOx), silicon nitride (SiNx), silicon oxynitride (SiOxNy), BCB (benzo-cyclo-butene), an acrylic material, polyimide, and/or the like. These may be used alone or in combination with each other.

However, the invention is not limited thereto. In an embodiment, the third gate insulating layer GI3 may include various insulating materials.

In an embodiment, the second interlayer insulating layer ILD2 may be disposed on the third gate insulating layer GI3. For example, the second interlayer insulating layer ILD2 may include an insulating material. Specifically, the second interlayer insulating layer ILD2 may include an organic material. More specifically, the second interlayer insulating layer ILD2 may include polyimide, polyacryl, polysiloxane, and/or the like. These may be used alone or in combination with each other.

However, the invention is not limited thereto. In an embodiment, the second interlayer insulating layer ILD2 may include various inorganic materials.

In an embodiment, the first via insulating layer VIA1 may be disposed on the second interlayer insulating layer ILD2.

For example, in an embodiment, the first via insulating layer VIA1 may include a material capable of providing a flat top surface. Specifically, the first via insulating layer VIA1 may include an organic insulating material. More specifically, the first via insulating layer VIA1 may include a photoresist, a polyacrylic resin, a polyimide resin, an acrylic resin, and/or the like. These may be used alone or in combination with each other.

However, the invention is not limited thereto. In an embodiment, the first via insulating layer VIA1 may include various inorganic materials.

For example, in an embodiment, an opening may be defined in the first via insulating layer VIA1. The opening may expose a portion of the dummy active pattern ACTD and a portion of the dummy gate pattern GED.

For example, in an embodiment, the opening may extend in the third direction DR3. In other words, the opening may extend in the third direction DR3 and expose each of the dummy active pattern ACTD and the dummy gate pattern GED. In other words, the opening may cross each of the dummy active pattern ACTD and the dummy gate pattern GED.

In an embodiment, the dummy electrode pattern VGH may be disposed in the opening. For example, the dummy electrode pattern VGH may include metal and/or alloy. Specifically, the dummy electrode pattern VGH may include aluminum (Al), silver (Ag), copper (Cu), molybdenum (Mo), chromium (Cr), titanium (Ti), tantalum (Ta), and/or the like. These may be used alone or in combination with each other.

In an embodiment, the second via insulating layer VIA2 may be disposed on both the dummy electrode pattern VGH and the first via insulating layer VIA1.

For example, in an embodiment, the second via insulating layer VIA2 may include a material capable of providing a flat top surface. Specifically, the second via insulating layer VIA2 may include an organic insulating material. More specifically, the second via insulation layer VIA2 may include a photoresist, a polyacrylic resin, a polyimide resin, an acrylic resin, and/or the like. These may be used alone or in combination with each other.

However, the invention is not limited thereto. In an embodiment, the second via insulating layer VIA2 may include various inorganic materials.

However, the invention is not limited thereto. The dummy electrode pattern VGH may include various metal materials.

FIG. 5 is exemplary, and the insulating layer and the metal pattern included in the display device 1 may be variously changed.

FIG. 6 is a view illustrating the sub compensation patterns included in the compensation pattern of FIG. 4, according to an embodiment.

For example, FIG. 6 is a view illustrating the plurality of sub compensation patterns adjacent to the pixel disposed in the uppermost pixel row RO1 among the plurality of pixels PX, according to an embodiment.

In an embodiment and referring to FIGS. 3, 4, and 6, each of the plurality of pixels PX may include a plurality of sub pixels. For example, the pixel disposed in the uppermost pixel row RO1 among the plurality of pixels PX (e.g., the first pixel PXa in FIG. 4) may include the first to third sub pixels SPX1, SPX2, SPX3, respectively.

However, the invention is not limited thereto. The pixel disposed in the uppermost pixel row RO1 among the plurality of pixels PX may include two, four or more sub pixels.

In an embodiment, each of the first to third sub pixels SPX1, SPX2, and SPX3, respectively, may have different internal capacitances. For example, the first sub pixel SPX1 is a pixel emitting red light, the second sub pixel SPX2 is a pixel emitting green light, and the third sub pixel SPX3 is a pixel emitting blue light. For example, a planar area of the third sub pixel SPX3 may be larger than each of a planar area of the first sub pixel SPX1 and a planar area of the second sub pixel SPX2. In this case, the internal capacitance of the third sub pixel SPX3 may be greater than the internal capacitance of each of the first and second sub pixels SPX1 and SPX2, respectively.

In an embodiment, the display device 1 may include the plurality of sub compensation patterns for compensating the deviation of the internal capacitance between the plurality of sub pixels. For example, the display device 1 may include the first sub compensation pattern 202c, the second sub compensation pattern 204c, and the third sub compensation pattern 206c. The first sub compensation pattern 202c, the second sub compensation pattern 204c, and the third sub compensation pattern 206c may be disposed adjacent to the first to third sub pixels SPX1, SPX2, and SPX3, respectively, in the first direction DR1.

In an embodiment, the plurality of sub compensation patterns may be adjacently disposed from the plurality of sub pixels included in the pixel disposed in the uppermost pixel row RO1 among the plurality of pixels PX in the first direction DR1. For example, the first sub compensation pattern 202c may be disposed adjacent to the first sub pixel SPX1 in the first direction DR1. The second sub compensation pattern 204c may be disposed adjacent to the second sub pixel SPX2 in the first direction DR1. The third sub compensation pattern 206c may be disposed adjacent to the third sub pixel SPX3 in the first direction DR1.

In an embodiment, each of the plurality of sub compensation patterns 202c, 204c, and 206c may provide the different compensation capacitances. For example, the internal capacitance of the third sub pixel SPX3 may be greater than the internal capacitance of each of the first and second sub pixels SPX1 and SPX2. In this case, the compensation capacitance provided by the third sub compensation pattern 206c may be smaller than the compensation capacitance provided by each of the first sub compensation pattern 202c and the second sub compensation pattern 204c. In other words, the sum of the compensation capacitance provided by the i-th sub compensation pattern and the internal capacitance of the i-th sub pixel may be constant. The i may be a natural number greater than or equal to 1.

Similar to the above, in an embodiment, the compensation capacitance may be determined based on the maximum value of the internal capacitance.

For example, in an embodiment, when the maximum value of the internal capacitance is about 3.7, the internal capacitance of the first sub pixel SPX1 is about 3.3, and the internal capacitance of the second sub pixel SPX2 is about 3.6, the display device 1 may include the first sub compensation pattern 202c and the second sub compensation pattern 204c. The first sub compensation pattern 202c may provide the compensation capacitance of about 0.4. The second sub compensation pattern 204c may provide the compensation capacitance of about 0.1.

In an embodiment, each of the plurality of sub compensation patterns 202c, 204c, and 206c may include the third compensation metal pattern 210c and the sixth compensation metal pattern 220c.

For example, in an embodiment, the first sub compensation pattern 202c may include the first sub metal pattern 212c and the second sub metal pattern 222c. The second sub metal pattern 222c may be disposed on the first sub metal pattern 212c.

In an embodiment, the second sub compensation pattern 204c may include the third sub metal pattern 214c and the fourth sub metal pattern 224c. The fourth sub metal pattern 224c may be disposed on the third sub metal pattern 214c.

In an embodiment, the third sub compensation pattern 206c may include the fifth sub metal pattern 216c and the sixth sub metal pattern 226c. The sixth sub metal pattern 226c may be disposed on the fifth sub metal pattern 216c.

For example, in an embodiment, the first sub compensation pattern 202c may provide the compensation capacitance of about 0.4. The second sub compensation pattern 204c may provide the compensation capacitance of about 0.1. In this case, a planar area of the second sub metal pattern 224c included in the second sub compensation pattern 204c may be about 4 times greater than a planar area of the second sub metal pattern 222c included in the first sub compensation pattern 202c.

A detailed description of an arrangement and structure of the plurality of sub compensation patterns 202c, 204c, and 206c will be described later with reference to FIGS. 8, 9, and 10.

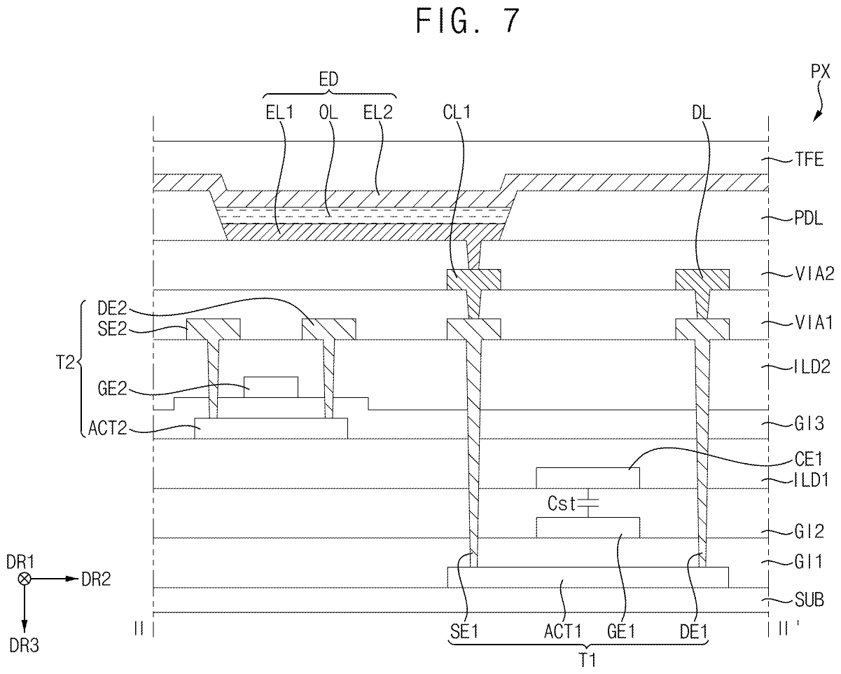

FIG. 7 is a cross-sectional view taken along line II-II′ of FIG. 6.

For example, FIG. 7 is a cross-sectional view of the first sub pixel SPX1 of FIG. 6, according to an embodiment. Each of the second sub pixel SPX2 and the third sub pixel SPX3 may have a substantially same structure as a structure of the first sub pixel SPX1. The first sub pixel SPX1 may correspond to the plurality of sub pixels included in the plurality of pixels PX of FIG. 1. Hereinafter, descriptions overlapping those of the display device 1 described above with reference to FIGS. 1, 2, 3, 4, 5, and 6 will be omitted or simplified.

In an embodiment and referring to FIGS. 6 and 7, at least one transistor may be disposed on the substrate SUB. In an embodiment, a first transistor T1 and a second transistor T2 may be disposed on the substrate SUB.

In an embodiment, the first transistor T1 may include a first active pattern ACT1, a first gate electrode GE1, a first source electrode SE1, and a first drain electrode DE1.

In an embodiment, the second transistor T2 may include a second active pattern ACT2, a second gate electrode GE2, a second source electrode SE2, and a second drain electrode DE2.

For example, in an embodiment, the first transistor T1 and the second transistor T2 may be disposed on different layers.

Specifically, in an embodiment, the first active pattern ACT1 may be disposed on the substrate SUB. For example, the first active pattern ACT1 may include amorphous silicon, polycrystalline silicon, single crystal silicon, low-temperature polycrystalline silicon, an oxide semiconductor, and/or the like. These may be used alone or in combination with each other.

In an embodiment, the first active pattern ACT1 may include a first source region, a first drain region, and a first channel region positioned between the first source region and the first drain region.

In an embodiment, the first gate insulating layer GI1 may be disposed on the substrate SUB and the first active pattern ACT1. The first gate insulating layer GI1 may include an organic insulating material and/or an inorganic insulating material.

In an embodiment, the first gate electrode GE1 may be disposed on the first gate insulating layer GI1. For example, the first gate electrode GE1 may include a metal or an alloy.

In an embodiment, the second gate insulating layer GI2 may be disposed on both the first gate insulating layer GI1 and the first gate electrode GE1. For example, the second gate insulating layer GI2 may include an organic insulating material and/or an inorganic insulating material.

In an embodiment, a first capacitor electrode pattern CE1 may be disposed on the second gate insulating layer GI2. A storage capacitor Cst may be formed in an area where the first capacitor electrode pattern CE1 and the first gate electrode GE1 overlap. For example, the first capacitor electrode pattern CE1 may include metal and/or alloy. Specifically, the first capacitor electrode pattern CE1 may include aluminum (Al), silver (Ag), copper (Cu), molybdenum (Mo), chromium (Cr), titanium (Ti), tantalum (Ta), and/or the like. These may be used alone or in combination with each other.

However, the invention is not limited thereto. In an embodiment, the first capacitor electrode pattern CE1 may include various metal materials.

In an embodiment, the first interlayer insulating layer ILD1 may be disposed on both the second gate insulating layer GI2 and the first capacitor electrode pattern CE1. For example, the first interlayer insulating layer ILD1 may include an insulating material.

In an embodiment, the second active pattern ACT2 may be disposed on the first interlayer insulating layer. For example, the first active pattern ACT1 may include amorphous silicon, polycrystalline silicon, single crystal silicon, low-temperature polycrystalline silicon, an oxide semiconductor, and/or the like. These may be used alone or in combination with each other.

In an embodiment, the second active pattern ACT2 may include a second source region, a second drain region, and a second channel region positioned between the second source region and the second drain region.

In an embodiment, the second active pattern ACT2 may include a material different from a material of the first active pattern ACT1. For example, the first active pattern ACT1 may include low-temperature polycrystalline silicon. The second active pattern ACT2 may include an oxide semiconductor.

In an embodiment, the third gate insulating layer GI3 may be disposed on both the first interlayer insulating layer ILD1 and the second active pattern ACT2. For example, the third gate insulating layer GI3 may include an organic insulating material and/or an inorganic insulating material.

In an embodiment, the second gate electrode GE2 may be disposed on the third gate insulating layer GI3. For example, the second gate electrode GE2 may include a metal and/or an alloy. Specifically, the second gate electrode GE2 may include aluminum (Al), silver (Ag), copper (Cu), molybdenum (Mo), chromium (Cr), titanium (Ti), tantalum (Ta), or the like. These may be used alone or in combination with each other.

However, the invention is not limited thereto. In an embodiment, the second gate electrode GE2 may include various metal materials.

In an embodiment, the second interlayer insulating layer ILD2 may be disposed on both the third gate insulating layer GI3 and the second gate electrode GE2. For example, the second interlayer insulating layer ILD2 may include an insulating material.

In an embodiment, first openings and second openings may be defined in the second interlayer insulating layer ILD2. For example, the first openings may expose a portion of the first active pattern ACT1. The second openings may expose a portion of the second active pattern ACT2.

In an embodiment, the first source electrode SE1 and the first drain electrode DE1 may be disposed in the first openings. The second source electrode SE2 and the second drain electrode DE2 may be disposed in the second openings. For example, each of the first source electrode SE1, the first drain electrode DE1, the second source electrode SE2, and the second drain electrode DE2 may include a metal and/or an alloy. Specifically, each of the first source electrode SE1, the first drain electrode DE1, the second source electrode SE2, and the second drain electrode DE2 may include aluminum (Al), silver (Ag), copper (Cu), molybdenum (Mo), chromium (Cr), titanium (Ti), tantalum (Ta), or the like. These may be used alone or in combination with each other.

However, the invention is not limited thereto. In an embodiment, each of the first source electrode SE1, the first drain electrode DE1, the second source electrode SE2, and/or the second drain electrode DE2 may include various metal materials.

In an embodiment, the first via insulating layer VIA1 may be disposed on both the second interlayer insulating layer ILD2, the first source electrode SE1, the first drain electrode DE1, the second source electrode SE2, and the second drain electrode DE2. For example, the first via insulating layer VIA1 may include the material capable of providing the flat top surface. Specifically, the first via insulating layer VIA1 may include an organic insulating material or an inorganic insulating material.

In an embodiment, a third opening and a fourth opening may be defined in the first via insulating layer VIA1. For example, the third opening may expose a portion of the first source electrode SE1. The fourth opening may expose a portion of the first drain electrode DE1.

In an embodiment, a first connection electrode CL1 may be disposed in the third opening. Any one of the plurality of data lines DL may be disposed in the fourth opening. For example, each of the first connection electrode CL1 and the plurality of data lines DL may include a metal and/or an alloy. Specifically, each of the first connection electrode CL1 and the plurality of data lines DL may include aluminum (Al), silver (Ag), copper (Cu), molybdenum (Mo), chromium (Cr), or titanium (Ti), tantalum (Ta), and/or the like. These may be used alone or in combination with each other.

However, the invention is not limited thereto. In an embodiment, each of the first connection electrode CL1 and the plurality of data lines DL may include various metal materials.

In an embodiment, the second via insulating layer VIA2 may be disposed on both the first via insulating layer VIA1, the first connection electrode CL1, and the plurality of data lines DL. For example, the second via insulating layer VIA2 may include the material capable of providing the flat top surface. Specifically, the second via insulating layer VIA2 may include an organic insulating material and/or an inorganic insulating material.

In an embodiment, a fifth opening may be defined in the second via insulating layer VIA2. For example, the fifth opening may expose a portion of the first connection electrode CL1.

In an embodiment, a lower electrode EL1 may be disposed in the fifth opening. For example, the lower electrode EL1 may include a metal and/or an alloy. Specifically, the lower electrode EL1 may include aluminum (Al), silver (Ag), copper (Cu), molybdenum (Mo), chromium (Cr), titanium (Ti), tantalum (Ta), and/or the like. These may be used alone or in combination with each other.

However, the invention is not limited thereto. In an embodiment, the lower electrode EL1 may include various metal materials.

In an embodiment, a pixel defining layer PDL may be disposed on the second via insulating layer VIA2. The pixel defining layer PDL may define a sixth opening exposing a top surface of the lower electrode EL1. For example, the pixel defining layer PDL may include an organic material. Specifically, the pixel defining layer PDL may include photoresist, polyacrylic resin, polyimide resin, acrylic resin, and/or the like. These may be used alone or in combination with each other.

In an embodiment, a light emitting layer OL may be disposed on the lower electrode EL1. The light emitting layer OL may be formed in the sixth opening defined by the pixel defining layer PDL. For example, the light emitting layer OL may include various light emitting materials. The light emitting material may emit light due to a voltage difference between the lower electrode EL1 and an upper electrode EL2. The upper electrode EL2 may be disposed on the light emitting layer OL. Accordingly, a light emitting element ED including the lower electrode EL1, the light emitting layer OL, and the upper electrode EL2 may be formed.

In an embodiment, an encapsulation layer TFE may be disposed on the light emitting element ED. The encapsulation layer TFE may cover the light emitting element ED to prevent oxidation of the light emitting element ED. For example, the encapsulation layer TFE may include an organic material and/or an inorganic material.

Accordingly, in an embodiment, the plurality of pixels PX may be formed in the display area AA. FIG. 7 is exemplary, and the insulating layer and the metal pattern included in the display device 1 may be variously changed.

FIG. 8 is a cross sectional view of a compensation pattern according to a first embodiment.

For example, in an embodiment, FIG. 8 is a cross-sectional view taken along line III-III′ of FIG. 6. Specifically, FIG. 8 is a cross-sectional view of the first sub compensation pattern 202c of FIG. 6. The first sub compensation pattern 202c may correspond to the plurality of compensation patterns 200 of FIG. 4. Hereinafter, descriptions overlapping those of the display device 1 described above with reference to FIGS. 1, 2, 3, 4, 5, 6, and 7 will be omitted or simplified.

In an embodiment and referring to FIGS. 2, 3, 4, 6, and 8, each of the plurality of compensation patterns 200 may include the first metal pattern 210 and the second metal pattern 220.

In an embodiment, the first metal pattern 210 may be disposed on the substrate SUB. Specifically, the first gate insulating layer GI1 may be disposed on the substrate SUB. The first metal pattern 210 may be disposed on the first gate insulating layer GI1.

In an embodiment, the first metal pattern 210 may include a same material as the first gate electrode GE1. For example, the first metal pattern 210 may include a metal and/or an alloy. Specifically, the first metal pattern 210 may include aluminum (Al), silver (Ag), copper (Cu), molybdenum (Mo), chromium (Cr), titanium (Ti), tantalum (Ta), and/or the like. These may be used alone or in combination with each other.

However, the invention is not limited thereto. In an embodiment, the first metal pattern 210 may include various metal materials.

In an embodiment, the first metal pattern 210 may provide a driving voltage to each of the plurality of pixels PX.

In an embodiment, the second metal pattern 220 may be disposed on the first metal pattern 210. Specifically, the second gate insulating layer GI2 may be disposed on both the first gate insulating layer GI1 and the first metal pattern 210. The second metal pattern 220 may be disposed on the second gate insulating layer GI2.

In an embodiment, the second metal pattern 220 may include a same material as the first capacitor electrode pattern CE1. For example, the second metal pattern 220 may include a metal and/or an alloy. Specifically, the second metal pattern 220 may include aluminum (Al), silver (Ag), copper (Cu), molybdenum (Mo), chromium (Cr), titanium (Ti), tantalum (Ta), and/or the like. These may be used alone or in combination with each other.

However, the invention is not limited thereto. In an embodiment, the second metal pattern 220 may include various metal materials.

In an embodiment, a first compensation capacitor C1 may be formed in an area where the second metal pattern 220 and the first metal pattern 210 overlap each other in the plan view. As described above, the first compensation capacitor C1 may be arranged such that the total cap is kept constant. For example, the first compensation capacitors C1 may be disposed correspondingly to each pixel column. The compensation capacitance provided by the first compensation capacitor C1 may be different for each pixel column.

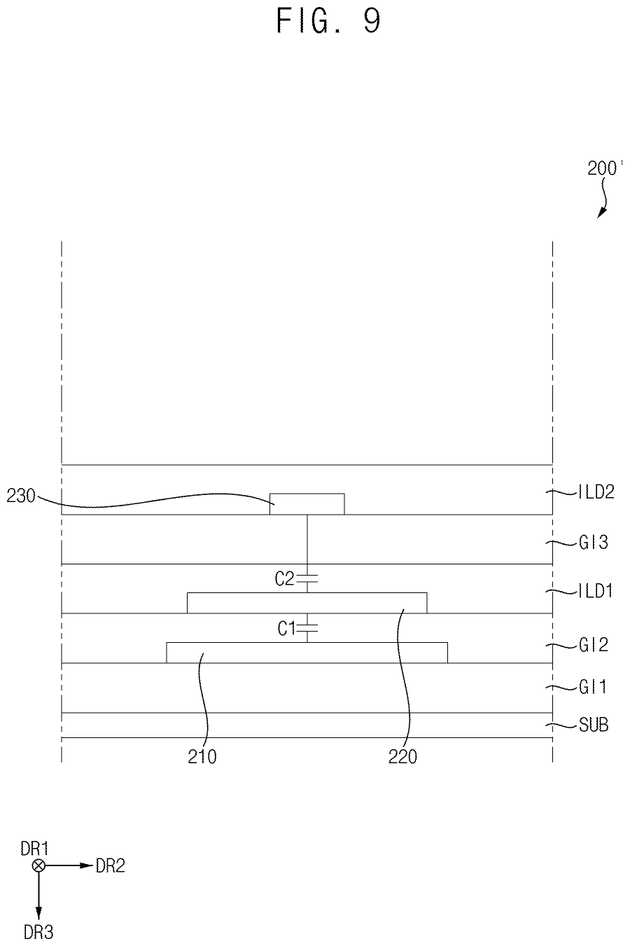

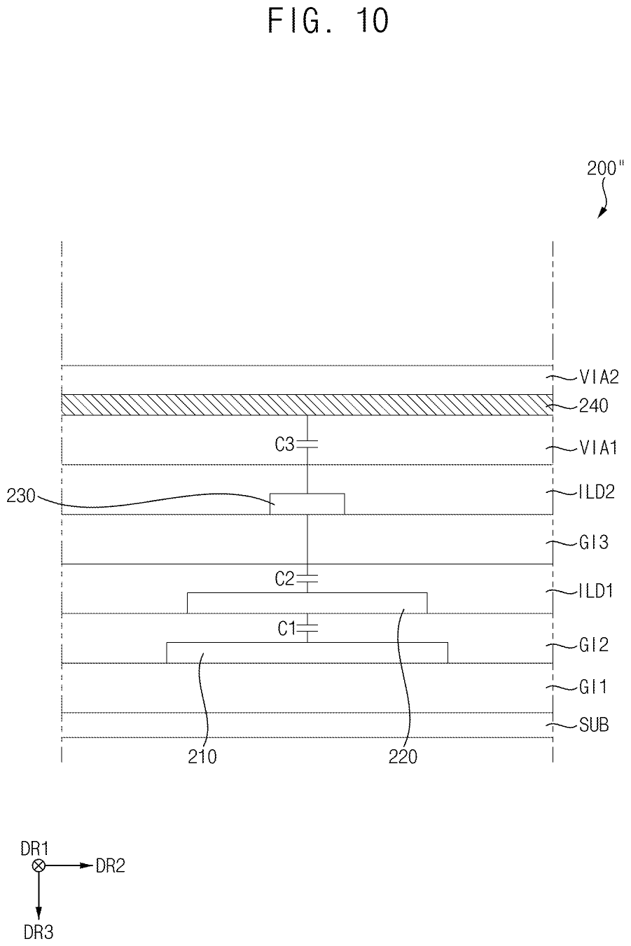

In an embodiment, the compensation capacitance may increase as the distance from the virtual line IL passing through the center CE of the display area AA and extending in the first direction DR1 is increased. To adjust the compensation capacitance, the plurality of compensation patterns 200 may further include other metal patterns. A detailed description thereof will be described later with reference to FIGS. 9 and 10.

In an embodiment, the first interlayer insulating layer ILD1, the third gate insulating layer GI3, and the second interlayer insulating layer ILD2 may be sequentially disposed on both the second gate insulating layer GI2 and the second metal pattern 220.

In an embodiment, a seventh opening may be defined in the second interlayer insulating layer ILD2. The seventh opening may expose a portion of the second metal pattern 220. A second connection electrode CL2 may be disposed in the seventh opening.

For example, in an embodiment, the second connection electrode CL2 may include a same material as each of the first source electrode SE1, the first drain electrode DE1, the second source electrode SE2, and the second drain electrode DE2. For example, the second connection electrode CL2 may include a metal and/or an alloy. Specifically, the second connection electrode CL2 may include aluminum (Al), silver (Ag), copper (Cu), molybdenum (Mo), chromium (Cr), or titanium (Ti), tantalum (Ta), and/or the like. These may be used alone or in combination with each other.

However, the invention is not limited thereto. In an embodiment, the second connection electrode CL2 may include various metal materials.

In an embodiment, the first via insulating layer VIA1 may be disposed on both the second interlayer insulating layer ILD2 and the second connection electrode CL2.

In an embodiment, an eighth opening may be defined in the first via insulating layer VIA1. The eighth opening may expose a portion of the second connection electrode CL2. Any one of the plurality of data lines DL may be disposed in the eighth opening. Any one of the plurality of data lines DL may contact the second connection electrode CL2.

In an embodiment, the second via insulating layer VIA2, the pixel defining layer PDL, and the encapsulation layer TFE may be sequentially disposed on both the first via insulation layer VIA1 and the plurality of data lines DL.

Accordingly, in an embodiment, the plurality of compensation patterns 200 may be disposed over the display area AA and the non-display area NA. FIG. 8 is exemplary, and the insulating layer and the metal pattern included in the display device 1 may be variously changed.

FIG. 9 is a cross-sectional view of a compensation pattern according to a second embodiment.

For example, each of a plurality of compensation patterns 200′ according to the second embodiment of FIG. 9 may be different in that the compensation patterns 200′ further include a third metal pattern 230 than each of the plurality of compensation patterns 200 according to the first embodiment of FIG. 8. Hereinafter, descriptions overlapping those of the display device 1 described above with reference to FIGS. 1, 2, 3, 4, 5, 6, 7, and 8 will be omitted or simplified.

Referring to FIGS. 2, 3, 4, 8, and 9, in an embodiment, each of the plurality of compensation patterns 200′ according to the second embodiment may include the first metal pattern 210, the second metal pattern 220, and the third metal pattern 230.

In an embodiment, the third metal pattern 230 may provide the driving voltage to each of the plurality of pixels PX.

In an embodiment, the third metal pattern 230 may be disposed on the second metal pattern 220. Specifically, the first interlayer insulating layer ILD1 may be disposed on both the second gate insulating layer GI2 and the second metal pattern 220. The third gate insulating layer GI3 may be disposed on the first interlayer insulating layer ILD1. The third metal pattern 230 may be disposed on the third gate insulating layer GI3.

In an embodiment, the third metal pattern 230 may include a same material as the second gate electrode GE2. For example, the third metal pattern 230 may include a metal and/or an alloy. Specifically, the third metal pattern 230 may include aluminum (Al), silver (Ag) copper (Cu), molybdenum (Mo), chromium (Cr), titanium (Ti), tantalum (Ta), and/or the like. These may be used alone or in combination with each other.

However, the invention is not limited thereto. In an embodiment, the third metal pattern 230 may include various metal materials.

In this case, in an embodiment, the third metal pattern 230 may be covered by the second interlayer insulating layer ILD2, and the second connection electrode CL2 may contact the third metal pattern 230.

In an embodiment, the first compensation capacitor C1 may be formed in the area where the second metal pattern 220 and the first metal pattern 210 overlap each other in the plan view. A second compensation capacitor C2 may be formed in an area where the second metal pattern 220 and the third metal pattern 230 overlap in the plan view.

Each of the plurality of compensation patterns 200′ according to the second embodiment of FIG. 9 may further include the second compensation capacitor C2 than each of the plurality of compensation patterns 200 according to the first embodiment of FIG. 8. Accordingly, each of the plurality of compensation patterns 200′ according to the second embodiment may provide a larger compensation capacitance than each of the plurality of compensation patterns 200 according to the first embodiment.

FIG. 10 is a cross-sectional view of a compensation pattern according to a third embodiment.

For example, each of a plurality of compensation patterns 200″ according to the third embodiment of FIG. 10 may be different in that the compensation patterns 200″ further include a fourth metal pattern 240 than each of the plurality of compensation patterns 200′ according to the second embodiment of FIG. 9. Hereinafter, descriptions overlapping those of the display device 1 described above with reference to FIGS. 1, 2, 3, 4, 5, 6, 7, 8, and 9 will be omitted or simplified.

Referring to FIGS. 2, 3, 4, 8, and 10, in an embodiment, each of the plurality of compensation patterns 200″ according to the third embodiment may include the first metal pattern 210, the second metal pattern 220, the third metal pattern 230, and the fourth pattern 240.

In an embodiment, the fourth metal pattern 240 may be disposed on the third metal pattern 230. Specifically, the fourth metal pattern 240 may be disposed on both the third metal pattern 230 and the third gate insulating layer GI3.

In an embodiment, the fourth metal pattern 240 may include a same material as each of the first source electrode SE1 and the first drain electrode DE1. For example, the fourth metal pattern 240 may include a metal and/or an alloy. Specifically, the fourth metal pattern 240 may include aluminum (Al), silver (Ag), copper (Cu), molybdenum (Mo), chromium (Cr), titanium (Ti), tantalum (Ta), and/or the like. These may be used alone or in combination with each other.

However, the invention is not limited thereto. In an embodiment, the fourth metal pattern 240 may include various metal materials.

In this case, in an embodiment, the fourth metal pattern 240 may be covered by the second via insulating layer VIA2, and the second connection electrode CL2 may contact the fourth metal pattern 240.

In an embodiment, the fourth metal pattern 240 may provide the driving voltage to each of the plurality of pixels PX.

In an embodiment, the first compensation capacitor C1 may be formed in the area where the second metal pattern 220 and the first metal pattern 210 overlap each other in the plan view. The second compensation capacitor C2 may be formed in the area where the second metal pattern 220 and the third metal pattern 230 overlap in the plan view. A third compensation capacitor C3 may be formed in an area where the third metal pattern 230 and the fourth metal pattern 240 overlap in the plan view.

Each of the plurality of compensation patterns 200″ according to the third embodiment of FIG. 10 may further include the third compensation capacitor C3 which is different than each of the plurality of compensation patterns 200′ according to the second embodiment of FIG. 9. Accordingly, each of the plurality of compensation patterns 200″ according to the third embodiment may provide a larger compensation capacitance than each of the plurality of compensation patterns 200′ according to the second embodiment.

In an embodiment, the plurality of compensation patterns 200, 200′, and 200″ described above with reference to FIGS. 8, 9, and 10 are examples, and a type, number, material, stacking order, etc. of the metal pattern included in the plurality of compensation patterns 200, 200′, and 200″, may be variously changed.

As described above, in an embodiment, the plurality of sub compensation patterns 202c, 204c, and 206c of FIG. 6 may differ only in size from the plurality of compensation patterns 200, 200′, and 200″. For example, the type, number, material, stacking order, etc. of the metal patterns included in the plurality of sub compensation patterns 202c, 204c, and 206c may be substantially the same as that described in the plurality of compensation patterns 200, 200′, and 200″. Shape, area, etc. of the plurality of sub compensation patterns 202c, 204c, and 206c may be variously changed.

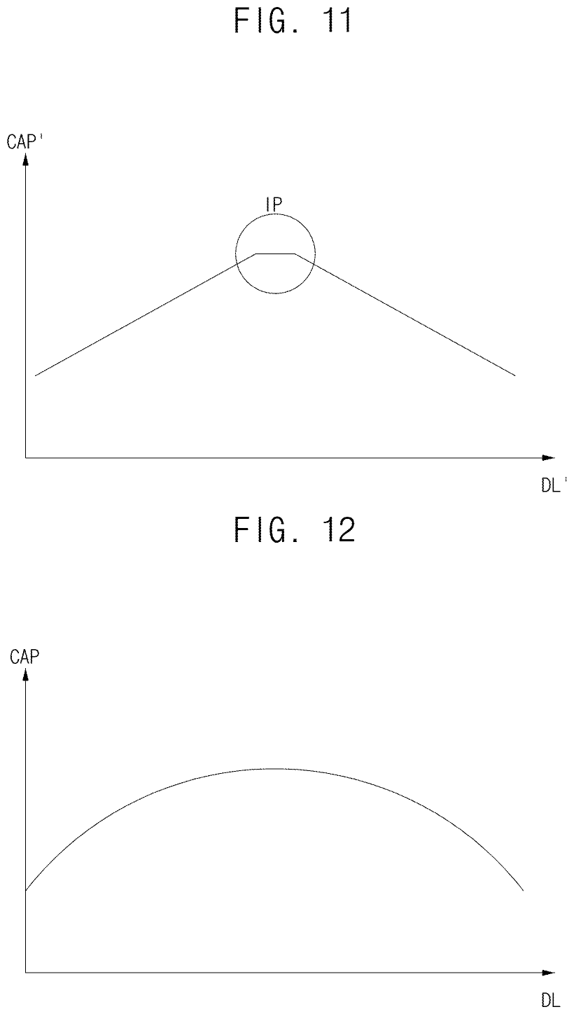

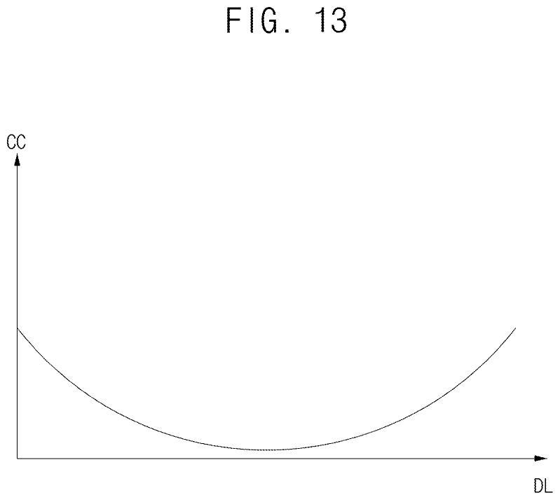

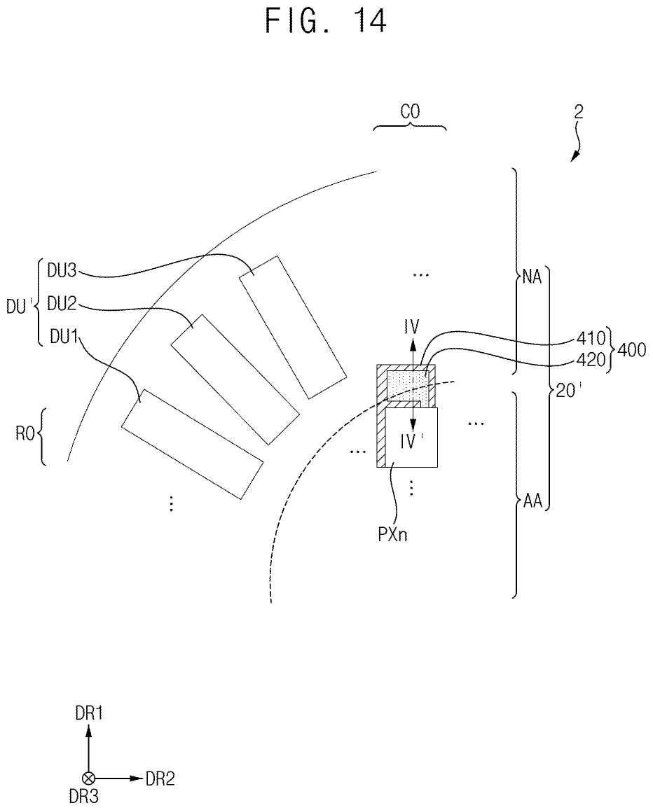

FIGS. 11, 12, and 13 are graphs illustrating an effect of the display devices according to embodiments.

Referring to FIG. 11, in a display device according to a comparative embodiment, an inflection point IP may be confirmed in a graph of internal capacitance CAP′ for each of a plurality of data lines DL′.

Unlike the display device 1 described above with reference to FIGS. 1, 2, 3, 4, 5, 6, 7, 8, 9, and 10, the display device according to the comparative embodiment might not include the plurality of compensation patterns 200 disposed adjacent to the pixel disposed in the uppermost pixel row RO1 among the plurality of pixels PX in the first direction DR1.

In this case, in an embodiment, the inflection point IP being sharply bent at a portion where the plurality of compensation patterns 200 are not disposed may be confirmed. Accordingly, in the display device according to the comparative embodiment, a horizontal line may occur according to the inflection point IP.

In addition, the display device according to the comparative embodiment may include a plurality of sub pixels. Unlike the display device 1 described above with reference to FIG. 6, the display device according to the comparative embodiment might not include the plurality of sub compensation patterns 202c, 204c, and 206c.

In this case, in an embodiment, color deviation may occur according to the deviation of the internal capacitance of each of the plurality of sub pixels.

Referring to FIGS. 2, 3, 4, 12, and 13, in the display device 1 according to embodiments, the inflection point IP might not be confirmed in a graph of internal capacitance CAP for each of the plurality of data lines DL.

The display device 1 according to embodiments may include the plurality of compensation patterns 200 disposed adjacent to the pixel disposed in the uppermost pixel row RO1 among the plurality of pixels PX in the first direction DR1.

In the display device 1 according to embodiments, the plurality of compensation patterns 200 may be disposed at positions corresponding to each of the plurality of data lines DL to provide different compensation capacitances CC such that the total cap is kept constant. Accordingly, in the display device 1 according to embodiments, occurrence of the horizontal line in the display device may be prevented or reduced.

In addition, in an embodiment, as described above with reference to FIG. 6, the display device 1 may include the first to third sub pixels SPX1, SPX2, and SPX3, respectively, and the first to third sub compensation patterns 202c, 204c, and 206c, respectively. In an embodiment, the plurality of sub compensation patterns 202c, 204c, and 206c may provide the different compensation capacitances CC.

As described above with reference to FIG. 2, in an embodiment, a compensation capacitance CC provided by each of the plurality of compensation patterns 200 may increase as the distance from the virtual line IL increases.

In this case, in an embodiment, the plurality of sub compensation patterns 202c, 204c, and 206c may prevent the color deviation caused by the deviation of the internal capacitance of the first to third sub pixels SPX1, SPX2, and SPX3, respectively.

FIG. 14 is a plan view illustrating a display device according to another embodiment. FIG. 15 is a cross-sectional view taken along line IV-IV′ of FIG. 14.

Hereinafter, descriptions overlapping those of the display device 1 with reference to FIGS. 1, 2, 3, 4, 5, 6, 7, 8, 9, 10, 11, 12, and 13 will be omitted or simplified.

In an embodiment and referring to FIGS. 14 and 15, a display device 2 may include a display panel 20′ and a plurality of dummy driving units DU′.

In an embodiment, the display panel 20′ may include the display area AA and the non-display area NA. As described above, the display area AA may have the non-rectangular planar shape.

In an embodiment, the plurality of data lines and the plurality of pixels PX may be disposed in the display area AA. Each of the plurality of pixels PX may be disposed at the position where the plurality of pixel rows RO and the plurality of pixel columns CO intersect. Each of the plurality of data lines may be connected to the plurality of pixels PX located in a corresponding pixel column among the plurality of pixel columns CO.

In an embodiment, in the plurality of pixel rows RO, the first to m-th pixels may be disposed in the direction opposite to the first direction DR1. The m may be a natural number greater than 1. The first to n-th pixels may be disposed in the plurality of pixel columns CO in the second direction DR2. The n may be a natural number greater than 1.

In an embodiment, the plurality of dummy driving units DU′ may be disposed in the non-display area NA. The plurality of dummy driving units DU′ may include a first dummy driving unit DU1, a second dummy driving unit DU2, and a third dummy driving unit DU3. The plurality of compensation patterns 200 may be positioned between the plurality of dummy driving units DU′ disposed in the non-display area NA and the plurality of pixels PX disposed in the display area AA.

In another embodiment, the plurality of dummy driving units DU′ may be omitted in the non-display area NA. A plurality of compensation patterns 400 may include a plurality of metal patterns (e.g., a first metal pattern 410 and a second metal pattern 420). As a length of the plurality of metal patterns in an extension direction increases, the metal patterns may interfere with the plurality of dummy driving units DU′ disposed in the non-display area NA. In this case, the dummy driving units DU′ disposed at a position where the interference occurs in the display device 2 may be omitted. For example, when a fourth dummy driving unit DU4 of FIG. 3 interferes with each of the plurality of compensation patterns 400, the fourth dummy driving unit DU4 of FIG. 3 may be omitted from the display device 2. In other words, if there is insufficient space in the display device 2 for disposing the plurality of compensation patterns 400, the display device 2 might not include the plurality of driving units DU′.

As described above with reference to FIGS. 11 and 12, in an embodiment, each of the plurality of data lines may have different internal capacitances. To compensate for the deviation of the internal capacitance between the plurality of data lines DL, the display device 2 may include the plurality of compensation patterns 400. In an embodiment, each of the plurality of compensation patterns 400 may provide the different compensation capacitance.

Accordingly, in an embodiment, the occurrence of the horizontal line according to the inflection point (e.g., the inflection point IP of FIG. 11) in the display device 2 may be prevented or reduced.

In an embodiment, the plurality of compensation patterns 400 may be disposed to correspond to each of the plurality of pixel columns CO. Similar to the above with reference to FIG. 6, the pixel (e.g., the n-th pixel PXn) disposed in the uppermost pixel row (e.g., the uppermost pixel row RO1 of FIG. 2) among the plurality of pixels PX. The display device 2 may include the plurality of sub compensation patterns (e.g., the first sub compensation pattern 202c, the second sub compensation pattern 204c, and the third sub compensation pattern 206c of FIG. 6) adjacent to the plurality of sub pixels.

Accordingly, in an embodiment, the occurrence of the color deviation according to the deviation of the internal capacitance of a plurality of sub pixels in the display device 2 may be prevented or reduced.

In an embodiment, the plurality of compensation patterns 400 may include the first metal pattern 410 and the second metal pattern 420. A first compensation capacitor C1′ may be formed in an area where the first metal pattern 410 and the second metal pattern 420 overlap each other in the plan view. For example, a length of the metal patterns constituting the first compensation capacitor C1′ of FIG. 15 in the extension direction (e.g., the second direction DR2) may be greater than a length of the metal patterns constituting the first compensation capacitor C1 of FIG. 8. Accordingly, the compensation capacitance provided by the first compensation capacitor C1′ of FIG. 15 may be greater than the compensation capacitance provided by the first compensation capacitor C1 of FIG. 8.

In an embodiment, in order to adjust the compensation capacitance, the display device 2 may be variously changed. For example, in the display device 2, an area of the metal patterns, a thickness of the insulating layer (e.g., the second gate insulating layer GI2) disposed between the metal patterns, and/or a dielectric constant of a material included in the insulating layer may be variously changed. Specifically, in order to increase the compensation capacitance, the area of an upper metal pattern among the metal patterns may be increased, the thickness of the insulating layer may be reduced, and/or the insulating layer may be formed of a material having a high permittivity.

Embodiments of the invention may be applied to a display device and an electronic device including the display device such as high-resolution smartphones, mobile phones, smart-pads, smart watches, tablet personal computers (PCs), in-vehicle navigation systems, televisions, computer monitors, notebook, computers, and/or the like, for example.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims. Moreover, the embodiments or parts of the embodiments may be combined in whole or in part without departing from the scope of the invention.

What is claimed is:

1. A display device comprising:
a substrate having a non-rectangular display area;
a plurality of pixels disposed in the display area and disposed in a plurality of pixel columns extending along a first direction and a plurality of pixel rows extending along a second direction crossing the first direction; and
a compensation pattern disposed adjacent to a pixel disposed in an uppermost pixel row among the plurality of pixels extending in the first direction.

2. The display device of claim 1, wherein the compensation pattern includes:
a first metal pattern disposed on the substrate; and
a second metal pattern disposed on the first metal pattern,
wherein a first compensation capacitor is formed in an area where the first metal pattern and the second metal pattern overlap each other.

3. The display device of claim 2, wherein,
the plurality of pixels includes a first transistor and a second transistor, wherein
the first transistor includes a first active pattern, a first gate pattern, a first source electrode, and a first drain electrode, and wherein
the first metal pattern includes a same material as the first gate pattern.

4. The display device of claim 3, further comprising:
a capacitor electrode pattern overlapping the first gate pattern, wherein,
a storage capacitor is formed in an area where the capacitor electrode pattern and the first gate pattern overlap each other, and wherein
the second metal pattern includes a same material as the capacitor electrode pattern.

5. The display device of claim 3, wherein the compensation pattern further includes:
a third metal pattern disposed on the second metal pattern, and
wherein a second compensation capacitor is formed in an area where the second metal pattern and the third metal pattern overlap each other.

6. The display device of claim 5, wherein,
the second transistor includes a second active pattern, a second gate pattern, a second source electrode, and a second drain electrode, and wherein
the third metal pattern includes a same material as the second gate pattern.

7. The display device of claim 5, wherein the compensation pattern further includes:
a fourth metal pattern disposed on the second metal pattern, and
wherein a third compensation capacitor is formed in an area where the third metal pattern and the fourth metal pattern overlap each other.

8. The display device of claim 7, wherein,
the fourth metal pattern includes a same material as the first source electrode and the first drain electrode.

9. The display device of claim 1, wherein the compensation pattern is disposed to correspond to each of the plurality of pixel columns.

10. The display device of claim 9, further comprising:
a plurality of data lines connected to the plurality of pixels located in a corresponding pixel column, extending in the first direction, and spaced apart from each other in the second direction,
wherein each of the plurality of data lines has a different internal capacitance, and
wherein the compensation pattern provides a compensation capacitance for compensating for a deviation in an internal capacitance between the plurality of data lines.

11. The display device of claim 10, wherein the compensation capacitance increases as a distance of a corresponding pixel column from a virtual line passing through a center of the display area and extending in the first direction increases.

12. A display device comprising:
a substrate having a non-rectangular display area;
a plurality of pixels disposed in the display area and disposed in a plurality of pixel columns extending along a first direction and a plurality of pixel rows extending along a second direction crossing the first direction; and
a compensation pattern including a first sub compensation pattern disposed adjacent to a first sub pixel included in a pixel disposed in an uppermost pixel row among the plurality of pixels in the first direction and a second sub compensation pattern disposed adjacent to a second sub pixel included in the pixel and having an internal capacitance different from an internal capacitance of the first sub pixel.

13. The display device of claim 12, wherein each of the first sub compensation pattern and the second sub compensation pattern provides a different compensation capacitance.

14. The display device of claim 12, wherein,
the plurality of pixels includes a first transistor and a second transistor, wherein
the first transistor includes a first active pattern, a first gate pattern, a first source electrode, and a first drain electrode, and wherein,
the compensation pattern includes:
a first metal pattern disposed on the substrate; and
a second metal pattern disposed on the first metal pattern,
wherein a first compensation capacitor is formed in an area where the first metal pattern and the second metal pattern overlap each other, and
wherein the first metal pattern includes a same material as the first gate pattern.

15. The display device of claim 14, further comprising:
a capacitor electrode pattern overlapping the first gate pattern, wherein,
a storage capacitor is formed in an area where the capacitor electrode pattern and the first gate pattern overlap each other, and wherein,
the second metal pattern includes a same material as the capacitor electrode pattern.

16. The display device of claim 15,
wherein the second transistor includes a second active pattern, a second gate pattern, a second source electrode, and a second drain electrode, and wherein,
the compensation pattern further includes:
a third metal pattern disposed on the second metal pattern, and
wherein a second compensation capacitor is formed in an area where the second metal pattern and the third metal pattern overlap each other, and
wherein the third metal pattern includes a same material as the second gate pattern.

17. The display device of claim 16, wherein the compensation pattern further includes:
a fourth metal pattern disposed on the second metal pattern, and
wherein a third compensation capacitor is formed in an area where the third metal pattern and the fourth metal pattern overlap each other, and
wherein the fourth metal pattern includes a same material as the first source electrode and the first drain electrode.

18. The display device of claim 12, wherein the compensation pattern is disposed to correspond to each pixel column.

19. The display device of claim 18, further comprising:
a plurality of data lines connected the plurality of pixels located in a corresponding pixel column, extending in the first direction, and spaced apart from each other in the second direction,
wherein each of the plurality of data lines has a different internal capacitance, and
wherein the compensation pattern provides a compensation capacitance for compensating for a deviation of the internal capacitance between the plurality of data lines.

20. The display device of claim 19, wherein the compensation capacitance increases as a distance of a corresponding pixel column from a virtual line passing through a center of the display area and extending in the first direction increases.
